(19) United States
(12) Patent Application Publication
(10) Pub. No.: US 2023/0125502 A1
(43) Pub. Date: Apr. 27, 2023

(54) SITU SENSING OF SURFACE CONDITION FOR POLISHING PADS

(71) Applicant: Applied Materials, Inc., Santa Clara, CA (US)

(72) Inventors: Shiyan JAYANATH, Santa Clara, CA (US); Daniel REDFIELD, Morgan Hill, CA (US); Ashwin CHOCKALINGAM, Santa Clara, CA (US)

(21) Appl. No.: 17/512,555

(22) Filed: Oct. 27, 2021

(51) Int. Cl. B24B 37/005; B24B 37/04; H01L 21/306

(52) U.S. Cl. CPC B24B 37/005; B24B 37/042; H01L 21/30625

(57) ABSTRACT

Embodiments described herein generally relate to a surface topology measurement device that enables mapping a surface profile of a polishing pad. Embodiments of the disclosure may include a method of measuring and/or adjusting a property of a polishing surface of a polishing pad disposed in a substrate processing system during processing or after one or more processes have been performed. The method can include positioning a surface topology measurement device such that the surface topology measurement device contacts the polishing surface of the polishing pad, generating a three-dimensional surface map of the polishing surface of the polishing pad, comparing the three-dimensional surface map of the polishing surface of the polishing pad to a predetermined threshold, and adjusting one or more properties of the substrate processing system based on the comparison of the three-dimensional surface map to the predetermined threshold.

### BACKGROUND

### Field

Embodiments described herein generally relate to a substrate processing system suitable for semiconductor processing. More specifically, embodiments described herein relate to mapping a surface profile of components during substrate processing operations.

### Description of the Related Art

An integrated circuit is typically formed on a substrate by the sequential deposition of conductive, semiconductive, or insulative layers on a semiconductor substrate. A variety of fabrication processes require planarization of a layer on the substrate. For example, one fabrication process involves depositing a filler layer over a non-planar surface and planarizing the filler layer. For certain applications, the filler layer is planarized until the top surface of a patterned layer is exposed. For example, a metal layer can be deposited on a patterned insulative layer to fill trenches and holes in the insulative layer. After planarization, the remaining portions of the metal in the trenches and holes of the patterned layer form vias, plugs, and lines to provide conductive paths between integrated circuits (ICs) on the substrate. As another example, a dielectric layer can be deposited over a patterned conductive layer, and then planarized to enable subsequent photolithographic processes.

Chemical mechanical planarization (“CMP”) is one accepted method of planarization. This planarization method typically requires that the substrate be mounted on a carrier head. The exposed surface of the substrate, the surface with the layer deposition, is typically placed against a rotating polishing pad. The carrier head provides a controllable load on the substrate to urge it against the polishing pad. A polishing slurry with abrasive particles is typically supplied to the surface of the polishing pad and spreads in between the substrate and the polishing pad. The polishing pad and the carrier head each rotate at a constant rotational speed and the abrasive slurry removes material from one or more of the layers. Material is removed in a planar fashion and the material removal process is symmetric about a central axis. However, the material removal process may be problematic because a polishing pad having an out of tolerance polishing surface may adversely affect the substrate. For example, a non-planar or an uneven polishing surface may asymmetrically remove material from the substrate. A low or high surface roughness may remove too little or too much material from the substrate. Debris accumulated during the polishing process may result in uneven polishing or wear a groove or channel into the substrate. The asymmetric polishing of the substrate may result in the circuits formed on a surface of the substrate to be of varying quality, which is not desirable.

Accordingly, there is a need in the art for methods of detecting and correcting a polishing surface beyond a predetermined threshold during a CMP process.

### SUMMARY

Embodiments of the present disclosure generally relate to polishing a substrate by use of a chemical mechanical planarization (“CMP”) process. In particular, embodiments herein provide methods for detecting and correcting a polishing surface beyond a predetermined threshold by use of a surface topology measurement device.

[To be completed after inventor review.]

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 depicts a top plan view illustrating one embodiment of a substrate processing system, according to one embodiment.

FIG. 2 depicts a schematic partial cross-sectional view of a polishing station having a pad conditioning assembly, according to one embodiment.

FIG. 3 schematically illustrates a polishing pad featuring shapes for polishing elements formed thereon, according to one embodiment.

FIG. 4 depicts a schematic view of a surface topology measurement device connected to a pad conditioning assembly, according to one embodiment.

FIGS. 5A-5C display a polishing pad at various points during a portion of a normal operation cycle, according to one embodiment.

FIG. 5D depicts a surface topology measurement device measuring a polishing surface of the polishing pad from FIG. 5C, according to one embodiment.

FIG. 6A is a schematic plan view of a conditioning arm positioned over a polishing pad, according to one embodiment.

FIGS. 6B and 6C depict a top view of a surface profile of a polishing pad as mapped by a surface topology measurement device, according to one embodiment.

FIG. 7 depicts a flowchart of a method of adjusting a polishing surface of a polishing pad disposed in a substrate processing system for use in semiconductor processing, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the present disclosure. However, it will be apparent to one of skill in the art that some embodiments of the present disclosure may be practiced without one or more of these specific details. In other instances, well-known features have not been described in order to avoid obscuring one or more embodiments of the present disclosure.

In view of the above, both a challenge and opportunity exist to improve the polishing surface of a polishing pad of a substrate processing system. Accordingly, a method and system are provided for detecting and correcting defects in and/or removing debris from a polishing surface that are beyond a predetermined threshold in size during one or more portions of a CMP process or between CMP processes.

Embodiments described herein generally relate to a surface topology measurement device that enables mapping a surface profile of a polishing pad. During processing, a polishing surface of the polishing pad may wear beyond a predetermined threshold, which can lead to inconsistent or undesirable polishing process results. For example, polishing elements of the polishing surface may wear below a usable height, which can cause slurry transport or retention issues. Uneven pressure applied to the polishing pad or an uneven substrate may wear certain portions of the polishing surface more than others, resulting in a polishing pad thickness differential that may polish subsequent substrates unevenly. Asperities may become embedded in the polishing surface and protrude from the polishing surface, which may scratch or embed in the surface of the substrate. Mapping the surface profile allows the surface profile to be compared to a predetermined threshold. However, the surface profile of the polishing pad may be difficult to map.

Current mapping solutions require the polishing pad to be removed or special mapping hardware to be installed, which requires the substrate processing system to be temporarily unusable during mapping or requires a replacement polishing pad. Current surface profile mapping solutions may further require minutes or even hours to complete or may not offer the resolution necessary for mapping the surface profile. Current in situ solutions only measure at a single point, which may not provide an accurate representation of the polishing surface given a surface roughness of and/or debris on the polishing surface may vary.

The methods and systems described herein may be useful for mapping the surface profile of the polishing pad at various points during a portion of a normal operation cycle. The mapping of the surface profile may be compared to a predetermined threshold, which may include previous measurements, to determine if the polishing pad is acceptable for use in the substrate processing system. This beneficially allows the polishing pad to be conditioned, rinsed to remove debris, or replaced as needed and may decrease damage to the substrates during operations.

### Example Substrate Processing System

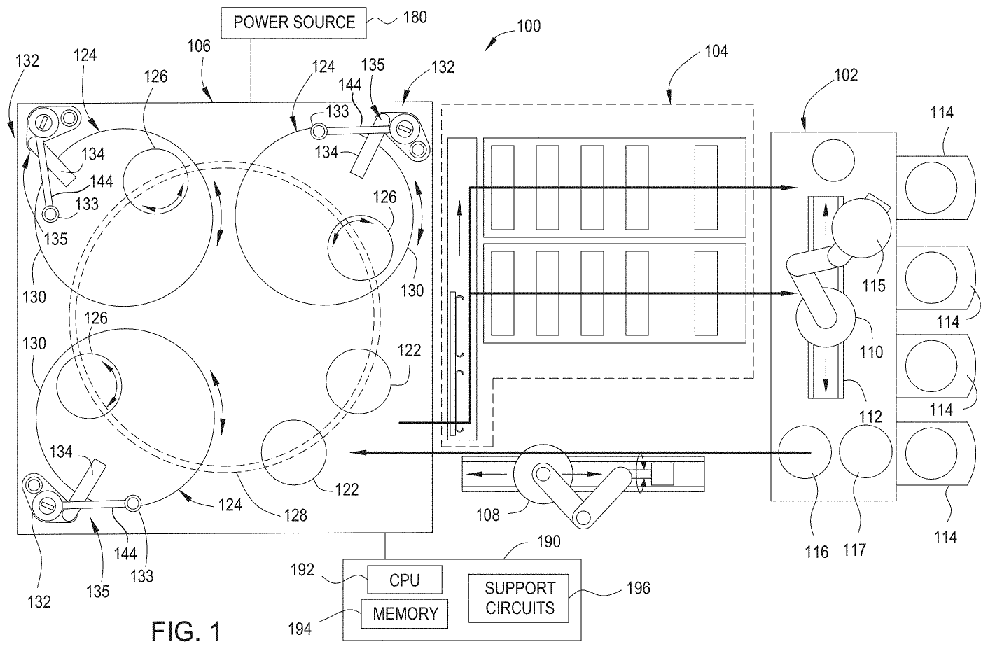

FIG. 1 depicts a top plan view illustrating one embodiment of a substrate processing system. In the depicted embodiment, the substrate processing system may be a chemical mechanical planarization (“CMP”) system 100 (referred to as system 100). The system 100 includes a factory interface module 102, a cleaner 104, and a polishing module 106. A wet robot 108 is provided to transfer the substrates 115 between the factory interface module 102 and the polishing module 106. The wet robot 108 may also be configured to transfer the substrates 115 between the polishing module 106 and the cleaner 104. The factory interface module 102 includes a dry robot 110 which is configured to transfer the substrates 115 between one or more cassettes 114, one or more metrology stations 117, and one or more transfer platforms 116. In one embodiment depicted in FIG. 1, four substrate storage cassettes 114 are shown. The dry robot 110 within the factory interface 102 has sufficient range of motion to facilitate transfer between the four cassettes 114 and the one or more transfer platforms 116. Optionally, the dry robot 110 may be mounted on a rail or track 112 to position the robot 110 laterally within the factory interface module 102. The dry robot 110 additionally is configured to receive the substrates 115 from the cleaner 104 and return the clean polished substrates to the substrate storage cassettes 114.

Still referring to FIG. 1, the polishing module 106 includes a plurality of polishing stations 124 on which the substrates 115 are polished while being retained in a carrier head 126. The polishing stations 124 are sized to interface with one or more carrier heads 126 so that polishing of a substrate 115 may occur in a single polishing station 124. The carrier heads 126 are coupled to a carriage (not shown) that is mounted to an overhead track 128 that is shown in phantom in FIG. 1. The overhead track 128 allows the carriage to be selectively positioned around the polishing module 106 which facilitates positioning of the carrier heads 126 selectively over the polishing stations 124 and load cup 122. In the embodiment depicted in FIG. 1, the overhead track 128 has a circular configuration which allows the carriages retaining the carrier heads 126 to be selectively and independently rotated over and/or clear of the load cups 122 and the polishing stations 124.

In one embodiment, as depicted in FIG. 1, three polishing stations 124 are shown located in the polishing module 106. At least one load cup 122 is in the corner of the polishing module 106 between the polishing stations 124 closest to the wet robot 108. The load cup 122 facilitates transfer between the wet robot 108 and the carrier heads 126.

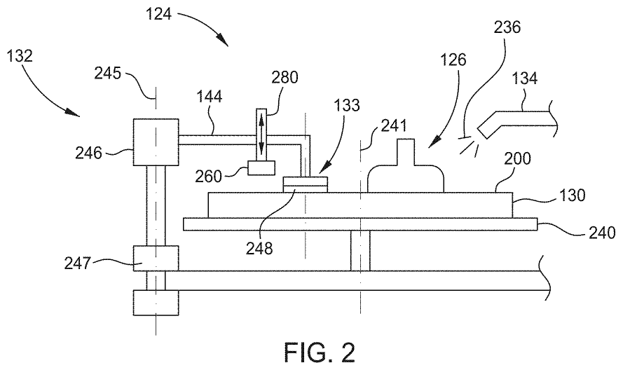

Each polishing station 124 includes a polishing pad 130 having a polishing surface (e.g., a polishing surface 200 in FIG. 2) to remove material from a substrate 115. For example, the carrier head 126 may be disposed above the polishing surface 200 and adapted to hold a substrate 115 against the polishing surface 200 to polish the substrate 115. Each polishing station 124 includes one or more carrier heads 126, a conditioning assembly 132 and a polishing fluid delivery module 135. In some embodiments, the polishing fluid delivery module 135 may comprise a fluid delivery arm 134 to deliver a fluid stream (e.g., a slurry 236 in FIG. 2) to a polishing station 124. In some embodiments, each polishing station 124 comprises a pad conditioning assembly 132. The system 100 is coupled with a power source 180.

A system controller 190 comprising a central processing unit (CPU) 192, memory 194, and support circuits 196, is connected to the system 100 to facilitate control of the system 100 and processes performed thereon. The CPU 192 may be one of any form of computer processor that can be used in an industrial setting for controlling various drives and pressures. The memory 194 is connected to the CPU 192. The memory 194, or computer-readable medium, may be one or more of readily available memory such as random access memory (RAM), read only memory (ROM), floppy disk, hard disk, or any other form of digital storage, local or remote. The support circuits 196 are connected to the CPU 192 for supporting the processor in a conventional manner. These circuits include cache, power supplies, clock circuits, input/output circuitry, subsystems, and the like. In some embodiments, the system controller 190 may be a non-transitory computer readable medium comprising computer-executable instructions that, when executed by a processing system (e.g., the CPU 192), cause the processing system to perform a method of adjusting a property of the polishing surface of the polishing pad.

FIG. 2 depicts a schematic partial cross-sectional view of a polishing station 124 having a pad conditioning assembly 132, according to one embodiment. The polishing pad 130 is disposed on or supported on a surface of a platen 240, which rotates the polishing pad 130 and the polishing surface 200 during processing. The fluid delivery arm 134 dispenses a fluid stream to the polishing station 124. For example, the fluid delivery arm 134 may dispense the slurry 236 to the rotating polishing pad 130 at a feed rate. The pad conditioning assembly 132 may comprise a pad conditioning head 133 (referred to as conditioning head 133) supported by a support assembly 246 with a conditioning arm 144 therebetween. The pad conditioning assembly 132 may have a second rotational axis 245. The conditioning head 133 may be used to restore polishing performance of the polishing surface 200.

The support assembly 246 is adapted to position the conditioning head 133 in contact with the polishing surface 200, and further is adapted to provide a relative motion therebetween. For example, the conditioning arm 144 may position the conditioning head in contact with the polishing surface 200. The conditioning arm 144 has a distal end coupled to the conditioning head 133 and a proximal end coupled to a base 247. The base 247 rotates to sweep the conditioning head 133 across the polishing surface 200 to condition the polishing surface 200.

The conditioning head 133 may further provide a controllable pressure or downforce to controllably press the conditioning head 133 toward the polishing surface 200. In one embodiment, the down force can be in a range between about 0.5 lbf (22.2 N) to about 14 lbf (62.3 N), for example, between about 1 lbf (4.45 N) and about 10 lbf (44.5 N). The conditioning head 133 generally rotates and/or moves laterally in a sweeping motion across the polishing surface 200. In one embodiment, the lateral motion of the conditioning head 133 may be linear or along an arc in a range of about the center of the polishing surface 200 to about the outer edge of the polishing surface 200, such that, in combination with the rotation of the platen 240, the entire polishing surface 200 may be conditioned. The platen 240 may have a first rotational axis 241. The conditioning head 133 may have a further range of motion to move the conditioning head 133 off of the platen 240 when not in use.

The pad conditioning assembly 132 may comprise a conditioning disk 248. For example, the pad conditioning assembly 132 may be coupled to a conditioning disk 248 and position the conditioning disk 248 against the polishing surface 200 of the polishing pad 130. The conditioning disk 248 dresses the polishing surface 200 of the polishing pad 130 by removing polishing debris and opening pores of the polishing pad 130 by use of the conditioning head 133.

For example, the conditioning head 133 is adapted to house the conditioning disk 248 to contact the polishing surface 200. The conditioning disk 248 may be coupled with the conditioning head 133 by passive mechanisms such as magnets and pneumatic actuators that take advantage of the existing up and down motion of the conditioning arm 144. The conditioning disk 248 generally extends beyond the housing of the conditioning head 133 by about 0.2 mm to about 1 mm in order to contact the polishing surface 200. The conditioning disk 248 can be made of nylon, cotton cloth, polymer, or other soft material that will not damage the polishing surface 200. Alternatively, the conditioning disk 248 may be made of a textured polymer or stainless steel having a roughened surface with diamond particles adhered thereto or formed therein. The diamond particles may range in size between about 30 microns to about 100 microns.

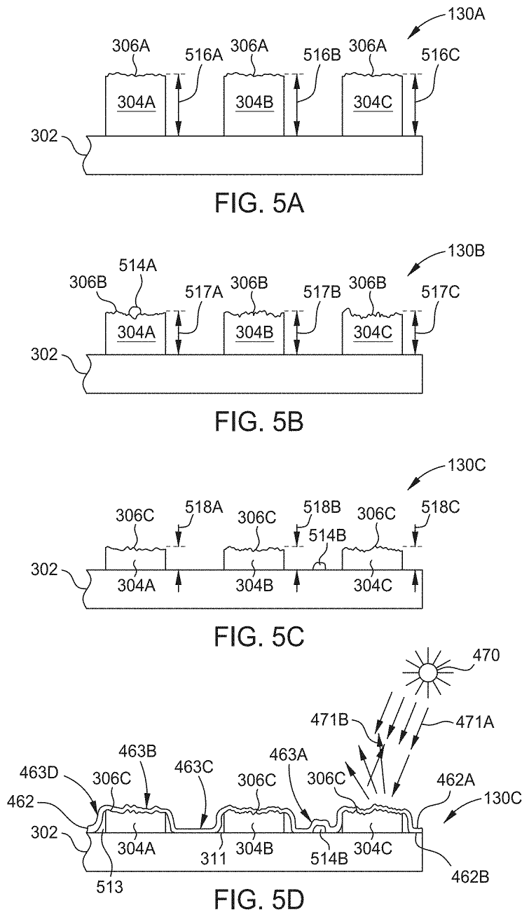

In the depicted embodiment, the pad conditioning assembly 132 further comprises a surface topology measurement device 260 (referred to as the device 260) coupled with the conditioning arm 144. The device 260 may be used to perform a set of three-dimensional measurements of the polishing surface 200. An actuator 280 may couple the device 260 to the conditioning arm 144. The actuator 280 may similarly provide a controllable pressure or downforce to controllably press the device 260 toward the polishing surface 200, although the down force may differ from the down force of the conditioning head 133. The device 260 allows a surface profile (e.g., a surface profile 650 in FIG. 5B) of the polishing pad 130 to be measured at various points during a portion of a normal operation cycle, while the system controller 190 allows the measurement data to be captured and displayed. For example, the device 260 maps a surface profile of the polishing surface 200.

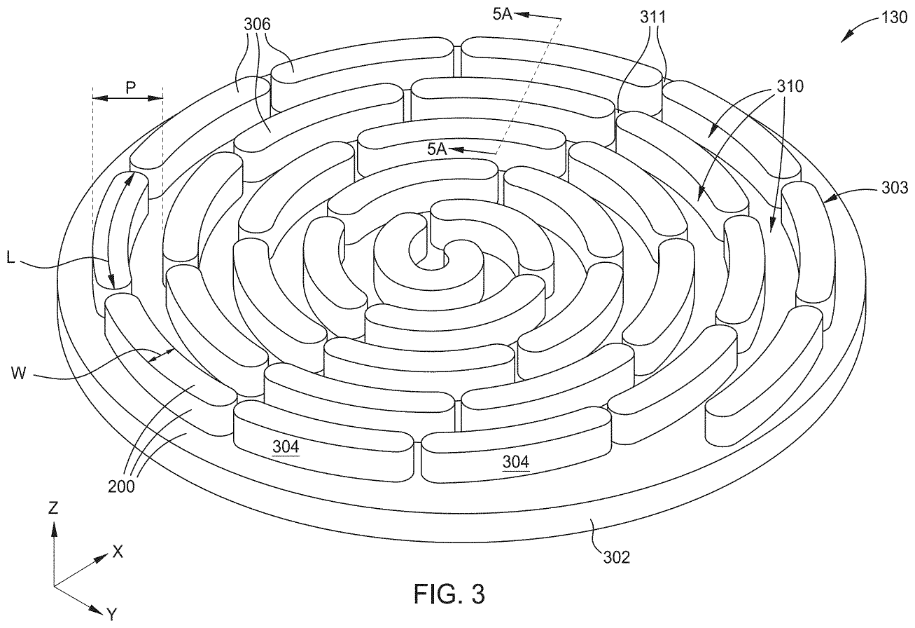

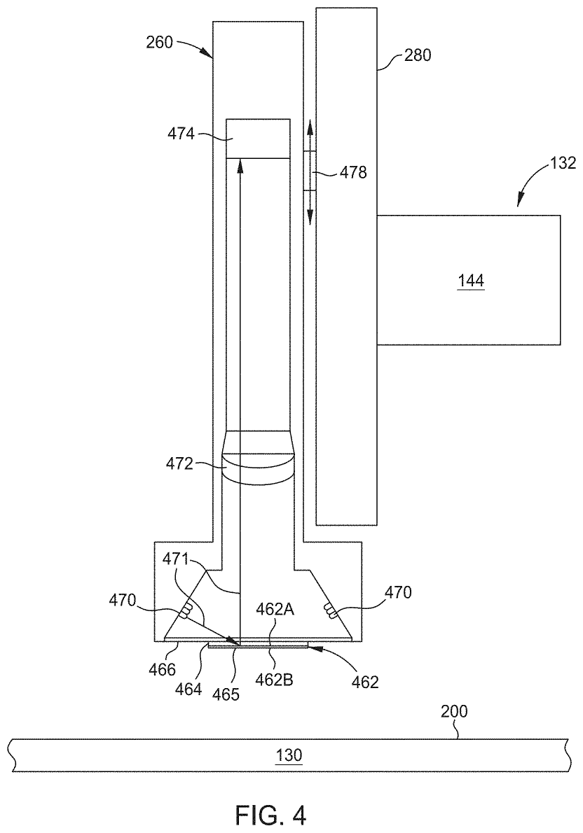

In the depicted embodiment, the device 260 uses tactile sensing to capture the surface profile. For example, the platen 240 may rotate the polishing pad 130 such that the area of the polishing surface 200 to be measured may be accessible by the device 260. The conditioning arm 144 may position the device 260 over an area of the polishing surface 200 to be measured by rotating the about the second rotational axis 245. The actuator 280 may position the device 260 such that the device 260 contacts and conforms to the polishing surface 200 to sense the surface profile as discussed in relation to FIGS. 4 and 5D. The device 260 may have a lateral resolution of at least about 2 microns (e.g., 1 micron).

In some embodiments, the device 260 may be referred to as a tactile sensor. In some embodiments, the device 260 may use light and polarization to sense the surface profile without contacting the surface. In some embodiments, the system controller 190 may control the positioning of the device 260 so that one or more points across a polishing pad can be measured and re-measured as necessary based on commands from the system controller 190. In some embodiments, the device may be positioned manually by a user. In some embodiments, the device 260 may allow the measurement data to be captured and displayed.

The system controller 190 may direct various operations of the system 100, such as controlling motion of the system 100. For example, the system controller 190 may move and control the position of the platen 240, the conditioning arm 144, and the actuator 280 such that the device 260 may sense the surface profile at a desired position as previously discussed. The system controller 190 may also interface with the device 260 to adjust a property of the polishing surface 200 of the polishing pad 130. For example, the system controller 190 may receive the set of three-dimensional measurements on the polishing surface 200 from the device 260. The system controller 190 may generate a three-dimensional surface map of the polishing surface 200 using the device 260, which may be based on the set of three-dimensional measurements. In some embodiments, the device 260 may generate the surface map, for example, in 5 seconds or less. The system controller 190 may compare the set of three-dimensional measurements on the polishing surface 200 or the surface map of the polishing surface 200 to a predetermined threshold. The system controller 190 may further adjust the system 100 or processing features of the system 100 based on the comparison of the set of three-dimensional measurements or surface map and the predetermined threshold. The predetermined threshold may be used to determine a condition or state of the polishing surface 200 and/or its polishing elements 304. For example, the predetermined threshold may be an allowable profile or geometry for the polishing surface 200.

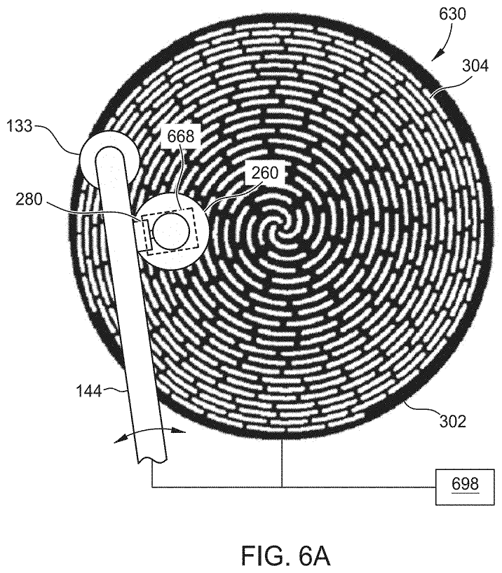

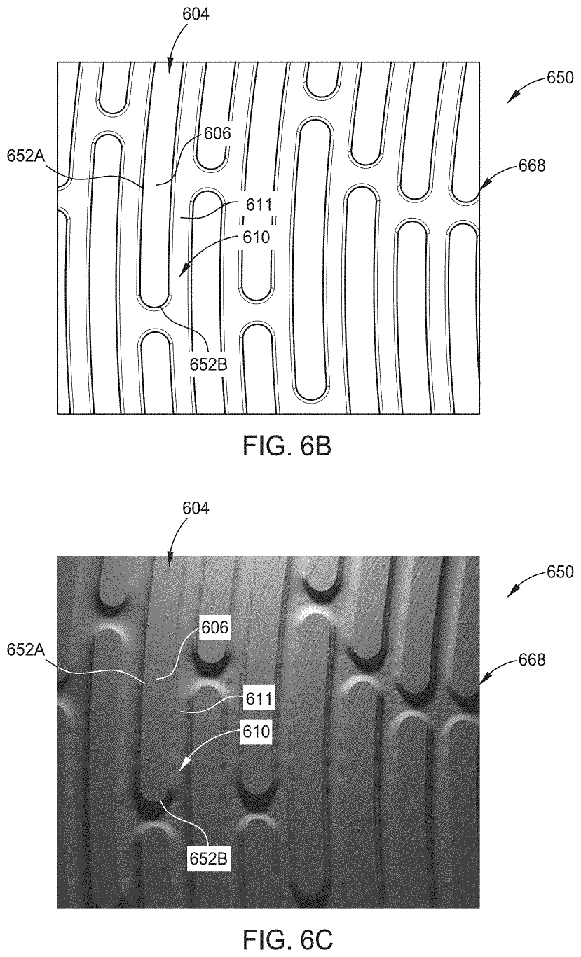

The predetermined threshold may include a threshold surface roughness or asperity density required to achieve desirable polishing results. The predetermined threshold may include a threshold height of features (e.g., polishing elements 304 in FIG. 3) of the polishing surface 200. The predetermined threshold may include a channel depth of channels (e.g., channels 310 in FIG. 3) formed in the polishing surface 200. In some embodiments, the predetermined threshold may be related to a previously generated surface map of the polishing surface 200. For example, due to the system controller's 190 control of the position of the device 260, by controlling of the actuating and positioning components (e.g., rotational actuators) of the conditioning arm 144, the surface map and the previously generated surface map can include at least a substantial portion of a same area of the polishing surface 200 of the polishing pad 130. A positioning system may be used to position the device 260 such that the surface map includes the at least a substantial portion of a same area of the polishing surface 200 as discussed in relation to FIG. 6A. The previously generated surface map may be a standard used for comparison instead of the surface map of the polishing surface 200. In some embodiments, the predetermined threshold may be any criteria used to determine the polishing pad 130 is acceptable for use in the system 100 including combinations of those described above. If any portion of the surface map of the polishing surface 200 exceeds the predetermined threshold, e.g. above an upper threshold or below a lower threshold, the system controller 190 may cause the system to perform a pad conditioning operation, a high pressure rinse of the pad surface to remove debris, or to send a reminder that the pad needs to be replaced as discussed in relation to FIG. 5D.

The configuration of the device 260 (e.g., attached to the conditioning arm 144 and interfaced with the system controller 190) beneficially allows the device 260 to operate in situ with the system 100 (FIG. 1). For example, the device 260 and the system controller 190 collectively map the surface profile, compare the surface profile to the predetermined threshold, and adjust a property of the polishing surface 200 of the polishing pad 130, all without removing the polishing pad 130 from the system 100.

In some embodiments, generating the three-dimensional surface map of the polishing surface 200 using the device 260 comprises several operations. For example, the platen 240 may be spun for a predetermined time at a predetermined speed. The device 260 may be positioned over a region of interest of the polishing surface 200. A measurement surface (e.g., a membrane 462 in FIG. 4) of the device 260 may be cleaned. The measurement surface may contact the region of interest of the polishing surface 200. The device 260 may acquire data to create the three-dimensional surface map of the polishing surface 200. The device 260 may be positioned away from the region of interest of the polishing surface. In some embodiments, the device 260 may be used to generate the surface map while the polishing surface 200 is wet, which beneficially allows the surface map to be generated without cleaning the polishing surface 200 and during more points of the operation cycle than if the polishing surface 200 is required to be dry.

### Polishing Pad Examples

FIG. 3 schematically illustrates the polishing pad 130 featuring shapes for polishing elements 304 formed thereon, according to one embodiment. FIG. 3 is a schematic isometric view of the polishing pad 130.

Here, the polishing pad 130 includes a foundation layer 302 and a polishing layer 303 disposed on the foundation layer 302 and integrally formed therewith to provide a continuous phase of polymer material across the interfacial boundary regions therebetween. The polishing layer 303 is formed of a plurality of discrete polishing elements 304 disposed on or partially within the foundation layer 302. The plurality of polishing elements 304 extend upwardly from an upward facing surface 311 of the foundation layer 302 to form a contact layer 306 of the polishing surface 200. The plurality of polishing elements 304 are spaced apart from one another to define a plurality of channels 310 therebetween. Here, the plurality of polishing elements 304 are arranged to form corresponding segments of a spiral pattern. The spiral pattern extends from an inner radius of the polishing pad 130 to an outer radius proximate to the circumference of the polishing pad 130. Here, individual ones of the plurality of polishing elements have an arc length L and a width W. For example, the arc length may be between about 2 mm and about 200 mm and a width may be between about 200 μm and about 10 mm, such as between about 1 mm and about 5 mm. A pitch P exists between the maximum radius sidewalls of radially adjacent polishing elements 304. The pitch may be between about 0.5 mm and about 20 mm, such as between about 0.5 mm and about 10 mm. In some embodiments, one or both of the arc length L, the width W, and the pitch P vary across a radius of the polishing pad 130 to define regions of different localized polishing performance.

In some embodiments, the polishing elements 304 may include a plurality of concentric annular rings, a plurality of spirals extending from a center of the polishing pad 130 to an edge of the polishing pad 130 or proximate thereto (such as discussed in relation to FIG. 6A), a plurality of discontinuous polishing elements 304 arranged in a spiral pattern on the foundation layer 302, or a plurality of cylindrical posts as the polishing elements 304 extending upwardly from the foundation layer 302.

In some embodiments, the polishing elements 304 are of any suitable cross-sectional shape, for example columns with toroidal, partial toroidal (e.g., arc), oval, square, rectangular, triangular, polygonal, irregular shapes in a section cut generally parallel to the underside surface of the pad 130, or combinations thereof. In some embodiment, the polishing pad 130 may have a plurality of discrete polishing elements 304 extending upwardly from the foundation layer 302, similar the cylindrical posts previously discussed, except that some of the polishing elements 304 are connected to form one or more closed circles. The one or more closed circles create dams to retain the polishing fluid during a CMP process.

### Surface Topology Measurement Device Examples

FIG. 4 depicts a schematic view of the device 260 connected to the pad conditioning assembly 132, according to one embodiment. As previously discussed in relation to FIG. 2, the actuator 280 connects the device 260 to the conditioning arm 144 of the pad conditioning assembly 132. In the depicted embodiment, the actuator 280 is a linear actuator. The linear actuator may be a belt drive actuator that includes a rotary actuator connected to a drive pulley, a guide pulley, and a belt or chain that wraps around the pulleys. A carriage 478 connects the device 260 to the actuator 280 such that the carriage 478 transfers motion of the actuator 280 to the device 260. For example, the carriage 478 may be connected to the belt of the actuator 280 such that when the rotary actuator rotates, the belt moves the carriage 478 towards or away from a position on the polishing pad 130.

FIG. 4 shows an embodiment of the device 260 as a tactile sensor. The device 260 comprises a membrane 462, and a support plate 466. A simplified version of the polishing pad 130 is shown (e.g., the polishing elements 304 and the channels 310 features discussed in relation to FIG. 3 are omitted). In some embodiments, the membrane 462 may comprise a pigment and may include an elastomer region 464 and a membrane region 465 on a side that contacts a surface, such as the polishing surface 200 of the polishing pad 130. In the depicted embodiment, the elastomer region 464 is transparent or clear such that the membrane region 465 is visible through the elastomer region 464. Another side of the elastomer region 464, such as a side opposite of the membrane region 465, may attach to the support plate 466. The support plate 466 is transparent or clear such that the membrane region 465 is visible through the support plate 466. The membrane 462, and some embodiments the elastomer region 464 and the membrane region 465 together, have a rubber-like elasticity and deform when forced against the polishing pad 130. For example, the controllable pressure or downforce exerted from the actuator 280 on the device 260 controllably presses the device 260 toward the polishing surface 200 such that the membrane 462 conforms to features and crevices of the polishing surface 200. In some embodiments, the device may include pneumatic ports configured to fluidly connect to a pressurized fluid source. For example, the pneumatic ports may connect to a pressurized inert gas or a compressed air supply. The pressurized fluid source applies a controllable pressure or downforce to the membrane 462 such that the membrane 462 conforms to features and crevices of the polishing surface 200.

The device 260 may use an optical-based system to take measurements. Several images may be captured to take the measurements, and the system controller 190 may analyze the images to derive the surface profile, which may be a three-dimensional surface map of the polishing surface 200 of the polishing pad 130. For example, the surface profile may be a surface topology map of polishing surface 200. One or more light emitting diodes (“LEDs”) 470 may direct light 471 to the support plate 466. As an outer surface 462B of the membrane 462 contacts the polishing surface 200, and deforms to conform to features (e.g., polishing elements 304 and channels 310 in FIG. 3) of the polishing surface 200 as discussed in relation to FIG. 5D. In some embodiments, the light 471 from the LEDs 470 travels through the transparent support plate 466 and reflects off an inner surface 462A of the membrane 462, which may have a known and consistent reflectance. In some embodiments, such as shown in FIG. 4, the inner surface 462A may be an inner surface of the membrane region 465 and the outer surface 462B may be an outer surface of the membrane region 465. The light 471 travels back through the support plate 466 and to a camera 474. In the depicted embodiment, a telecentric lens 472 is disposed between the support plate 466 and the camera 474. Light 471 reflected off the membrane 462 travels through the telecentric lens 472, which may offer constant magnification regardless of the object's distance or location in the field of view. The constant magnification beneficially ensures an orthographic projection of the object on the camera 474 and allows the device 260 to accurately map and measure the surface profile of the polishing surface 200.

There are many benefits to the device 260 being a tactile sensor instead of mapping the polishing surface 200 of the polishing pad 130 from a distance (e.g., by use of camera) or directly measuring the polishing surface 200. For example, taking a direct image or measurement of the polishing surface 200 may not be possible due to slurry, water droplets, or other material disposed thereon that will scatter the light and thus provide an unreliable image of the pad surface. However, in some cases, mapping the polishing surface 200 from a distance may be desirable if the polishing surface 200 may not be contacted.

In some embodiments, the device 260 may map and measure the surface profile with a gap between the polishing surface 200 and the device 260. In some embodiments, the LEDs 470 may be used to illuminate the polishing surface 200 when capturing the images. In some embodiments, the camera may be a polarization camera, which may use a filter, such as a polarized filter, to split incoming light from the LEDs into multiple phases. The polarized filter and polarization camera may beneficially allow the device 260 to map and measure the surface profile without taking multiple images because the polarization may effectively split one image into multiple images where each image has light polarized at a different phase. The system controller 190 may compare the multiple images of different phases to map or measure the surface profile.

In some embodiments, the LEDs may use different wavelengths. In some embodiments, the LEDs may comprise more than one wavelength. For example, the LEDs may comprise at least one of a wavelength corresponding to a color red, blue, green, or white.

In some embodiments, the actuator 280 may be a mechanical or electromechanical actuator such as a ball screw, roller screw, or lead screw designs driven actuator. In some embodiments, actuator 280 may be hydraulic, pneumatic, or piezoelectric linear actuator.

### Sensing a Surface Profile of a Polishing Pad Examples

FIGS. 5A-5C display the polishing pad 130 at various points during a portion of a normal operation cycle, according to one embodiment. In particular, FIGS. 5A-5C show how the polishing elements 304 may wear in one embodiment.

FIG. 5A shows a polishing pad 130A (e.g., the polishing pad 130 at a first point of the operation cycle) and its polishing elements 304A-C. The polishing elements 304A-C each have a surface roughness and together form a contact layer 306A, which contacts a surface to be polished (e.g., a surface of the substrate 115 in FIG. 1). The polishing elements 304A-C are each a height 516A-C, respectively, as measured from the foundation layer 302 to the contact layer 306A. The heights 516A-C may be about the same, or may vary. While polishing the surface to be polished, the polishing elements 304A-C wear, the heights 516A-C decrease, and the surface roughness may change. For example, the polishing elements 304A-C may wear as shown in FIGS. 5B and 5C.

The heights 516A-C may be difficult to measure. For example, the surface roughness of the polishing elements 304A-C may result in different measurement values for the heights 516A-C depending on where the measurement is taken. The surface roughness of the polishing elements 304A-C may result in a jagged surface with peaks and valleys. The detected heights 516A-C may vary depending on whether they were measured to a peak, a valley, or a point in between. Therefore, it is challenging to measure the heights 516A-C. In one embodiment, the device 260 may be beneficially used to measure the heights, such as the heights 516A-C, within an area that is covered by the outer surface 462B of the membrane 462 as described in relation to FIG. 5D.

FIG. 5B shows a polishing pad 130B (e.g., the polishing pad 130 at a second point of the operation cycle) and its polishing elements 304A-C. The polishing elements 304 are worn from polishing such that a height 517A-C of each polishing element 304A-C, respectively, is less than the heights 516A-C shown in FIG. 5A. A contact layer 306B is similar to the contact layer 306A, except the contact layer 306B is at the second point of the operation cycle. A surface roughness of the polishing elements 304A-C in FIG. 5B may be different from the surface roughness discussed in relation to FIG. 5A.

Throughout the operation cycle, asperities 514 may become embedded in or extend from the polishing surface of the polishing pad 130. For example, an asperity 514A may become embedded in or extend from the polishing element 304A at the contact layer 306B. The asperity 514A may be material that is dislodged during processing, such as a piece of the substrate 115 (FIG. 1) or an abrasive from the slurry 236 (FIG. 2). The asperities 514 may result in inconsistent polishing during processing and may be undesirable. For example, the asperity 514A may protrude from the contact surface 306B as a high spot, which results in the asperity 514A contacting the surface to be polished on the substrate 115 before the substrate 115 surface contacts the surface of the contact layer 306B. Consequently, the asperity 514A may result in a groove or channel worn into the surface of the substrate 115 that is to be polished, thus creating a scratch. Further, the asperity 514A may become loose or dislodge during processing and may become embedded into the surface of the substrate that is to be polished, contaminating or scratching the surface of the substrate. Thus, asperities 514 embedded in the polishing pad 130 are not desirable. However, the asperity 514A may be too small to detect by eye through visual inspection. The device 260 may be beneficially used to detect the asperities 514, such as the asperity 514A, as described in relation to FIG. 5D. The asperities 514 may be removed by conditioning the polishing pad 130C with the conditioning head 133 (FIG. 2).

In some embodiments, the detected heights 517A-C may be below a threshold height and the feed rate of the slurry 236 may be adjusted based on the detected heights 517A-C. For example, the feed rate of the slurry 236 provided to the polishing pad 130B may be a lower feed rate than the amount provided to the polishing pad 130A because less of the slurry 236 will be retained between the polishing elements 304 (e.g., in the channels 310 in FIG. 3) of the polishing pad 130B than the polishing pad 130A.

FIG. 5C shows a polishing pad 130C (e.g., the polishing pad 130 at a third point of the operation cycle) and its polishing elements 304A-C. A height 517A-C of each polishing element 304A-C, respectively, is less than the heights 516A-C shown in FIG. 5A and the heights 517A-C shown in FIG. 5B.

In some embodiments, the heights 518A-C may be below a threshold height and the polishing pad 130C may need to be replaced. For example, once the heights 518A-C are past the threshold height, the channels 310 of the polishing pad 130C may be too shallow to retain the slurry 236 and effectively polish the substrate 115. Further, an asperity 514B may be embedded in the foundation layer 302. The asperity 514B may restrict flow of the slurry 236, which may adversely affect the polishing results. The asperity 514B may adversely affect polishing if dislodged.

In some embodiments, the heights 516-518 may refer to an average height of the polishing elements 304. For example, the heights 516-518 may be an average distance from the foundation layer 302 to the contact layer 306. The average distance may account for the surface roughness of the polishing elements 304, such that the average distance includes measurements to peaks and valleys of the contact layer 306. In some embodiments, the heights 516-518 may refer to an average height of each polishing element 304. For example, the heights 516A-C may refer to an average height of each polishing element 304A-C. In some embodiments, the heights 516-518 may include a plurality of measurements for each polishing element 304A-C. For example, the heights 516-518 may include a minimum and maximum height. The heights 516-518 may include any number of points along the contact layer 306.

In some embodiments, the heights 516-518 of each polishing element, which may be an average height of each polishing element 304, may be compared to a predetermined threshold when comparing the surface map.

FIG. 5D depicts the device 260 measuring the polishing surface 200 of the polishing pad 130C from FIG. 5C, according to one embodiment. In particular, FIG. 5D shows the membrane 462 of the device 260 conforming to the polishing surface 200. The device 260 may be used to check if the polishing elements 304A-C are below the threshold height as discussed in relation to FIG. 5C.

The device 260 may contact the polishing surface 200 as described in relation to FIG. 4, for example, by a downforce from the actuator 280 (FIG. 4). The membrane 462 conforms to the asperity 514B at a first portion 463A of the membrane 462. The membrane 462 conforms to the polishing elements 304A-C and the peaks and valleys of the contact layer 306 at a second portion 463B. The membrane 462 further wraps around the polishing elements 304A-C and contacts the upward facing surface 311 of the foundation layer 302 at a third portion 463C. A gap 513 may exist between the membrane 462 and the polishing surface 200 for at least a portion of the polishing surface 200. For example, gaps 513 (one of which is labeled) are formed between where the polishing elements 304 connect to the foundation layer 302. A fourth portion 463D of the membrane 462 bounds the gap 513. The gaps 513 may result from a sudden change in a direction of the polishing surface 200. For example, the polishing elements 304A-C may sharply transition from the contact layer 306C to the foundation layer 302 such that an angle between the polishing elements 304A-C and the foundation layer 302 is about 90 degrees. The membrane 462 may be able to conform to directional changes up to a slope threshold or an angle threshold, which may be less than about 90 degrees. Thus, the gaps 513 may form when the directional changes exceed the slope threshold or the angle threshold and the fourth portion 463D of the membrane 462 may be sloped.

As discussed in relation to FIG. 4, light 471A travels from the LEDs 470 to the membrane. Light 471B is reflected off the membrane 462 and to the camera 474 (FIG. 4). The device 260 uses the membrane 462, which conforms to the polishing surface 200, to generate a three-dimensional surface map of the polishing surface 200 as discussed in relation to FIGS. 6B and 6C. Measurements may be taken from the surface map (e.g., the surface topology map) and may beneficially be used to improve the polishing performance of the polishing pad 130. For example, the mapping may be used to adjust one or more properties of the system 100 (FIG. 1).

In some embodiments, adjusting one or more properties of the system 100 may include adjusting at least one property of at least one of the plurality of polishing elements 304 or the plurality of channels 310 of the polishing surface 200, such as by using the pad conditioning assembly 132 (FIG. 1) to remove material from the polishing pad 130. In some embodiments, adjusting one or more properties of the system 100 may include removing the asperities 514 from the polishing surface 200 of the polishing pad 130, such as by conditioning the polishing pad. In some embodiments, adjusting one or more properties of the system 100 may include removing debris or embedded contaminants using at least one of a high-pressure rinse or a suction module. For example, stream of fluid (e.g., deionized water) or compressed gas (e.g., compressed air) may be used to remove the debris. A vacuum may also be used to remove the debris. In some embodiments, adjusting the one or more properties of the system 100 may also include adjusting the feed rate of the slurry 236 as discussed in relation to FIG. 5B. In some embodiments, adjusting one or more properties of the system 100 may include replacing the polishing pad 130.

In some embodiments, the mapping may be used to alter a surface property of the polishing pad 130 based on the comparison of the measurements of the surface map of the polishing surface 200 to a predetermined threshold. For example, altering a surface property of the polishing pad 130 may include at least one of abrading the polishing surface 200, rinsing the polishing surface 200, increasing a temperature at the polishing surface 200, and the like.

FIG. 6A is a schematic plan view of the conditioning arm 144 positioned over a polishing pad 630 by use of the system controller 190, according to one embodiment. In particular, FIG. 6A shows how the conditioning arm 144 may position the conditioning head 133 and the device 260 over the polishing pad 630. The polishing pad 630 is similar to the polishing pad 130 (FIG. 3), except the polishing pad 630 has more polishing elements 304 and the polishing elements 304 form four spirals extending from a center of the polishing pad 630 to an edge of the polishing pad 630.

FIG. 6A includes a pixel chart having white regions (regions in white pixels) that represent the polishing elements 304 and black regions (regions in black pixels) that represent the foundation layer 302, as viewed from above. The conditioning arm 144 may rotate about an axis (e.g., the second rotational axis 245 in FIG. 2) to position the conditioning head 133 and/or the device 260. The platen 240 (FIG. 2) may rotate about an axis (e.g., the first rotational axis 241 in FIG. 2) to position the conditioning head 133 and/or the device 260 over a desired portion of the polishing pad 630. For example, a field of view 668 for the device 260 is shown over a first portion of the polishing pad 630. The field of view 668 may be the boundary for the images used to map the surface profile. In some embodiments, the field of view 668 may be at or near a boundary or an edge of the membrane 462 (FIG. 4). The rotation of the conditioning arm 144 and the rotation of the polishing pad 630 allow the field of view 668 to be positioned such that the field of view 668 may access portions of the polishing surface 200 (FIG. 3) used during processing. In some embodiments, the field of view 668 may access the entire polishing surface 200.

In the depicted embodiment, a positioning system 698 controls the positioning of the platen 240, the conditioning arm 144, and the device 260. For example, the positioning system may rotate the platen 240 to a desired angular position, rotate the conditioning arm 144 such that the field of view 668 of the device 260 is positioned over a region of interest of the polishing surface 200 (e.g., the desired portion of the polishing pad 630), and position the device 260 such that the device 260 contacts the polishing surface 200 to generate a surface map. The positioning system 698 may position the device 260 such that the surface map includes at least a substantial portion of a same area of the polishing surface 200 as a previously generated surface map. In some embodiments, the positioning system 698 may be part of the system controller 190 described in relation to FIG. 1. For example, the positioning system 698 may be computer executable instructions that reside in the memory 194 and are executed by the CPU 192.

In some embodiments, the surface profile of the polishing pad 630 may be mapped through a repetitive process. For example, when at a first position, the device 260 may contact and map a first surface profile of a first portion as previously discussed. The device 260 may move away from the first position on the polishing pad 630. The platen 240 and/or the conditioning arm 144 may rotate to re-position the device 260 at a second position over a second portion. The device 260 may contact and map the second surface profile at the second position, and the entire process may be repeated for a third portion and the like.

FIGS. 6B and 6C depict a top view of a surface profile 650 of the polishing pad 630 as mapped by the device 260, according to one embodiment. In particular, FIGS. 6B and 6C shows a mapping of the polishing surface 200 in the field of view 668 shown in FIG. 6A. FIG. 6B is an illustration of the surface profile 650 and FIG. 6C is an image of the surface profile 650 as captured by the device 260 (FIG. 4).

The surface profile 650 includes mapped polishing elements 604 (one of which is labeled) a mapped upward facing layer 611 of the foundation layer 302 (FIG. 5D), and mapped channels 610 formed between the polishing elements 604 and the upward facing layer 611. A mapped contact layer 606 is formed by flat tops of the mapped polishing elements 604. The mapped polishing elements 604 may include a sloped perimeter 652 where the mapped polishing elements 604 meet the mapped upward facing layer 611. For example, the mapped polishing elements 604 may include a sloped side 652A and a sloped end 652B. The sloped perimeter 652 may not actually be present on the polishing pad 630 and may result from gaps 513 between the membrane 462 and the polishing surface 311 as discussed in relation to FIG. 5D. For example, the sloped perimeter 652 may result from the fourth portion 463D of the membrane 462.

### Example Method for Adjusting a Property of a Polishing Surface of a Polishing Pad

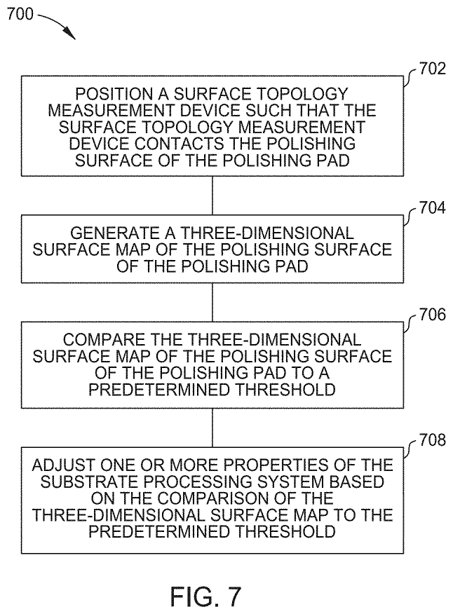

FIG. 7 depicts a flowchart of a method 700 of adjusting a property of a polishing surface of a polishing pad disposed in a system, according to one embodiment. The method 700 begins at block 702 with positioning a surface topology measurement device such that the surface topology measurement device contacts the polishing surface of the polishing pad as discussed in relation to FIGS. 2, 4, and 5D.

The method continues at block 704 with generating a three-dimensional surface map of the polishing surface of the polishing pad as discussed in relation to FIGS. 2 and 3.

The method 700 continues at block 706 with comparing the three-dimensional surface map of the polishing surface of the polishing pad to a predetermined threshold as discussed in relation to FIGS. 2 and 3.

The method 700 continues at block 708 with adjusting one or more properties of the substrate processing system based on the comparison of the three-dimensional surface map to the predetermined threshold as discussed in relation to FIGS. 2 and 5B-5D.

In some embodiments, the polishing pad further comprises a foundation layer having an upward facing surface. The polishing surface comprises a plurality of polishing elements extending upwardly from the upward facing surface of the foundation layer and a plurality of channels formed by the plurality of polishing elements and the upward facing surface. Adjusting the one or more properties of the substrate processing system comprises adjusting at least one property of at least one of the plurality of polishing elements or the plurality of channels of the polishing surface

Some embodiments further include adjusting the at least one property of the at least one of the plurality of polishing elements or the plurality of channels of the polishing surface comprises using a pad conditioner to remove material from the polishing pad.

In some embodiments, comparing the surface map of the polishing surface of the polishing pad to the predetermined threshold comprises at least one of comparing a surface roughness of at least one polishing element of the plurality of polishing elements of the polishing surface to a threshold surface roughness or comparing a channel depth of at least one channel of the plurality of channels of the polishing surface to a threshold channel depth.

Some embodiments further include detecting asperities on the polishing surface of the polishing pad, wherein adjusting the one or more properties of the substrate processing system comprises removing the asperities from the polishing surface of the polishing pad.

In some embodiments, comparing the surface map of the polishing surface of the polishing pad to the predetermined threshold comprises comparing the surface map of the polishing surface to a three-dimensional, previously generated surface map of the polishing surface.

In some embodiments, the surface map and the previously generated surface map comprise at least a portion of a same area of the polishing surface of the polishing pad.

In some embodiments, the substrate processing system provides a slurry to the polishing pad at a feed rate. Adjusting the one or more properties of the substrate processing system comprises adjusting the feed rate of the slurry.

In some embodiments, adjusting the one or more properties of the substrate processing system comprises replacing the polishing pad.

Some embodiments further include generating a three-dimensional, adjusted surface map of the polishing surface of the polishing pad using the surface topology measurement device and comparing the adjusted surface map of the polishing surface of the polishing pad to the predetermined threshold.

In some embodiments, generating the surface map of the polishing surface of the polishing pad is performed while the polishing surface is wet.

In some embodiments, the surface topology measurement device has a lateral resolution of at least about 2 microns.

In some embodiments, generating a three-dimensional surface map of the polishing surface of the polishing pad using the surface topology measurement device includes contacting a region of interest on the polishing surface with a membrane of the surface topology measurement device. Generating the surface map includes acquiring surface topology data based on the contact of the membrane with the polishing surface. The three-dimensional surface map include the surface topology data. Generating the surface map includes positioning the surface topology measurement device at a second region of interest on the polishing surface.

In some embodiments, the surface topology measurement device generates the surface map in 5 seconds or less.

In some embodiments, the polishing surface of the polishing pad includes a plurality of polishing elements. In some embodiments, comparing the surface map includes calculating an average height of each polishing element of the plurality of polishing elements and comparing the average height of each polishing element to the predetermined threshold.

Note that FIG. 7 is just one example of a method, and other methods including fewer, additional, or alternative steps are possible consistent with this disclosure.

As used herein, the term “about” may refer to a +/−10% variation from the nominal value. It is to be understood that such a variation can be included in any value provided herein.

Embodiments of the disclosure provided herein may include a method of measuring and/or adjusting a property of a polishing surface of a polishing pad disposed in a substrate processing system during processing or after one or more processes have been performed. The method can include positioning a surface topology measurement device such that the surface topology measurement device contacts the polishing surface of the polishing pad, generating a three-dimensional surface map of the polishing surface of the polishing pad, comparing the three-dimensional surface map of the polishing surface of the polishing pad to a predetermined threshold, and adjusting one or more properties of the substrate processing system based on the comparison of the three-dimensional surface map to the predetermined threshold.

Aspects of the present disclosure have been described above with reference to specific embodiments. Persons skilled in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

1. A method of adjusting a property of a polishing surface of a polishing pad disposed in a substrate processing system, comprising:
positioning a surface topology measurement device such that the surface topology measurement device contacts the polishing surface of the polishing pad;
generating a three-dimensional surface map of the polishing surface of the polishing pad;
comparing the three-dimensional surface map of the polishing surface of the polishing pad to a predetermined threshold; and
adjusting one or more properties of the substrate processing system based on the comparison of the three-dimensional surface map to the predetermined threshold.

2. The method of claim 1, wherein:
the polishing pad further comprises a foundation layer having an upward facing surface;
the polishing surface comprises a plurality of polishing elements extending upwardly from the upward facing surface of the foundation layer and a plurality of channels formed by the plurality of polishing elements and the upward facing surface; and
adjusting the one or more properties of the substrate processing system comprises adjusting at least one property of at least one of the plurality of polishing elements or the plurality of channels of the polishing surface.

3. The method of claim 2, wherein adjusting the at least one property of the at least one of the plurality of polishing elements or the plurality of channels of the polishing surface comprises using a pad conditioner to remove material from the polishing pad.

4. The method of claim 3, wherein comparing the surface map of the polishing surface of the polishing pad to the predetermined threshold comprises at least one of:
comparing a surface roughness of at least one polishing element of the plurality of polishing elements of the polishing surface to a threshold surface roughness; or
comparing a channel depth of at least one channel of the plurality of channels of the polishing surface to a threshold channel depth.

5. The method of claim 1, further comprising detecting asperities on the polishing surface of the polishing pad, wherein adjusting the one or more properties of the substrate processing system comprises removing the asperities from the polishing surface of the polishing pad.

6. The method of claim 1, wherein comparing the surface map of the polishing surface of the polishing pad to the predetermined threshold comprises comparing the surface map of the polishing surface to a three-dimensional, previously generated surface map of the polishing surface.

7. The method of claim 6, wherein the surface map and the previously generated surface map comprise at least a portion of a same area of the polishing surface of the polishing pad.

8. The method of claim 1, wherein:
the substrate processing system provides a slurry to the polishing pad at a feed rate; and
adjusting the one or more properties of the substrate processing system comprises adjusting the feed rate of the slurry.

9. The method of claim 1, wherein adjusting the one or more properties of the substrate processing system comprises replacing the polishing pad.

10. The method of claim 1, further comprising:
generating a three-dimensional, adjusted surface map of the polishing surface of the polishing pad using the surface topology measurement device; and
comparing the adjusted surface map of the polishing surface of the polishing pad to the predetermined threshold.

11. The method of claim 1, wherein generating the surface map of the polishing surface of the polishing pad is performed while the polishing surface is wet.

12. The method of claim 1, wherein the surface topology measurement device has a lateral resolution of at least about 2 microns.

13. The method of claim 1, wherein:
generating a three-dimensional surface map of the polishing surface of the polishing pad using the surface topology measurement device comprises:
contacting a region of interest on the polishing surface with a membrane of the surface topology measurement device;
acquiring surface topology data based on the contact of the membrane with the polishing surface, wherein the three-dimensional surface map comprises the surface topology data; and
positioning the surface topology measurement device at a second region of interest on the polishing surface.

14. The method of claim 1, wherein the surface topology measurement device generates the surface map in 5 seconds or less.

15. The method of claim 1, wherein:
the polishing surface of the polishing pad comprises a plurality of polishing elements; and
comparing the surface map comprises:
calculating an average height of each polishing element of the plurality of polishing elements; and
comparing the average height of each polishing element to the predetermined threshold.

16. A substrate processing system, comprising:
a polishing pad having a polishing surface configured to remove material from a substrate;
a platen supporting the polishing pad and configured to rotate the polishing surface;
a conditioning head configured to restore polishing performance of the polishing surface;
a conditioning arm coupled to the conditioning head and configured to position the conditioning head in contact with the polishing surface;
a surface topology measurement device coupled to the conditioning arm and configured to perform a set of three-dimensional measurements on the polishing surface;
an actuator coupled to the surface topology measurement device and configured to position the surface topology measurement device against the polishing surface of the polishing pad;
a carrier head disposed above the polishing surface and adapted to hold a substrate against the polishing surface; and
a system controller, wherein the system controller is configured to:
receive the set of three-dimensional measurements on the polishing surface from the surface topology measurement device;
compare the set of three-dimensional measurements on the polishing surface to a predetermined threshold; and
adjust the system based on the comparison of the set of three-dimensional measurements and the predetermined threshold.

17. A substrate processing system, comprising:
a polishing pad disposed on a surface of a platen, wherein the platen has a first rotational axis;
a pad conditioning assembly coupled to a conditioning disk and configured to position the conditioning disk against a polishing surface of the polishing pad, wherein the pad conditioning assembly has a second rotational axis; and
a non-transitory computer readable medium comprising computer-executable instructions that, when executed by a processing system, cause the processing system to perform a method of adjusting a property of the polishing surface of the polishing pad, the method comprising:
positioning a surface topology measurement device such that the surface topology measurement device contacts the polishing surface of the polishing pad;
generating a three-dimensional surface map of the polishing surface of the polishing pad;
comparing the surface map of the polishing surface of the polishing pad to a predetermined threshold; and
adjusting one or more processing properties of the substrate processing system based on the comparison of the surface map meeting the predetermined threshold.

18. The system of claim 17, wherein comparing the surface map of the polishing surface of the polishing pad to the predetermined threshold comprises comparing the surface map of the polishing surface to a three-dimensional, previously generated surface map of the polishing surface.

19. The system of claim 18, further comprising a positioning system, wherein the positioning system is used to position the surface topology measurement device such that the three-dimensional surface map and the previously generated surface map comprise at least a portion of a same area of the polishing surface of the polishing pad.

20. The system of claim 17, wherein the method of adjusting a property of the polishing surface of the polishing pad further comprises:
rotating the platen for a predetermined time at a predetermined speed;
positioning the surface topology measurement device over a region of interest of the polishing surface;
cleaning a measurement surface of the surface topology measurement device;
contacting the region of interest of the polishing surface with the measurement surface of the surface topology measurement device;
acquiring data with the surface topology measurement device to create a three-dimensional surface map of the polishing surface; and
positioning the surface topology measurement device away from the region of interest of the polishing surface.
